(19) United States
(12) Patent Application Publication
(10) Pub. No.: US 2026/0086150 A1
(43) Pub. Date: Mar. 26, 2026

(54) COMPOSITE SYSTEM DESIGN FOR COMMON MODE ERROR CORRECTION

(71) Applicant: Xcerra Corporation, Norwood, MA (US)

(72) Inventors: Sukhjot Bassi, San Jose, CA (US); Yue Liu, Quincy, MA (US); Richard Liggiero, Tewksbury, MA (US); David Leip, Ithaca, NY (US)

(21) Appl. No.: 18/898,449

(22) Filed: Sep. 26, 2024

(51) Int. Cl. G01R 31/319

(52) U.S. Cl. CPC G01R 31/31924; G01R 31/31905; G01R 31/3191

(57) ABSTRACT

In an aspect, a semiconductor device tester is disclosed. A semiconductor device tester may provide a device under test (DUT) in a semiconductor device testing system. A semiconductor device tester may apply a testing input signal from a test signal source circuitry to a DUT, the testing signal having a common mode error. A semiconductor device tester may determine, at a measurement unit connected to the test signal source circuitry, a voltage at an output signal to a DUT. A semiconductor device tester may communicate a voltage to a feedback subcircuit. A semiconductor device tester may provide, by a feedback subcircuit, a feedback signal to a testing signal to compensate for a common mode error.

### BACKGROUND

### Field

The disclosed technology generally relates to measurements using composite systems and more particularly to reducing common mode error in semiconductor testers.

### Description of the Related Art

A semiconductor device tester is used in the semiconductor industry to test electric devices. The semiconductor device tester conducts testing based on predetermined settings which are dependent upon the characteristics of semiconductor device to be tested. During testing, various testing systems configured to manipulate the input device's operating conditions are applied to the input device and the result is recorded.

The semiconductor device being tested, often referred to as device under test (“DUT”) is subjected to various input signals to obtain output signals, which may be indicative of the functionalities and performance of the DUT. During electrical testing, the electric devices may be first electrically connected to a contactor which includes a set of pins for delivering the input signals to the DUT. These pins come into contact with the input leads of the DUT.

Feedback systems can be implemented to control, regulate, and influence the output signal levels and response through a desired transfer function. Feedback systems can be used to detect a difference between the desired output and the actual output response resulting from processing an input to a controlled system, and the detected difference can be fed back to the system to dynamically reduce the difference. Feedback control systems are generally designed to quickly and accurately respond to changes to maintain or control its output to the desired response. The errors within the feedback control systems can result in inaccuracy in the output of the feedback control system and the semiconductor device tester. Accordingly, reduction and/or compensation of error may improve the performance and reliability of the semiconductor device tester (e.g., by minimizing the total measurement error (“TME”) of the semiconductor device tester).

### SUMMARY

For purposes of summarizing the disclosure and the advantages achieved over the prior art, certain objects and advantages of the disclosure are described herein. Not all such objects or advantages may be achieved in any particular embodiment. Thus, for example, those skilled in the art will recognize that the invention may be embodied or carried out in a manner that achieves or optimizes one advantage or group of advantages as taught herein without necessarily achieving other objects or advantages as may be taught or suggested herein.

All of these embodiments are intended to be within the scope of the invention herein disclosed. These and other embodiments will become readily apparent to those skilled in the art from the following detailed description of the preferred embodiments having reference to the attached figures, the invention not being limited to any particular preferred embodiment(s) disclosed.

In some aspects, the techniques described herein relate to a method of correcting common mode error in a composite closed-loop system. The method includes providing a device under test (DUT) in a semiconductor device testing system. The method includes applying a testing input signal from a test signal source circuitry to the DUT, the testing signal having a common mode error. The method includes determining, at a measurement unit connected to the test signal source circuitry, a voltage at an output signal to the DUT. The method includes communicating the voltage to a feedback subcircuit; and providing, by the feedback subcircuit, a feedback signal to the testing signal to compensate for the common mode error.

In some embodiments, the method includes providing, by the feedback subcircuit, the feedback signal to a measurement subcircuit, determining, based on a measurement output of the measurement subcircuit, a correction factor for the testing signal, the correction factor configured to compensate for the common mode error, and applying the correction factor to the testing signal to compensate for the common mode error. In some embodiments, the measurement subcircuit does not have additional circuitry configured to compensate for the common mode error. In some embodiments, the test signal source circuitry has a first transfer function G(s), the feedback subcircuit has a second transfer function H(s), and a ratio of the output signal to the DUT to the testing input signal is expressed as a negative feedback control system transfer function represented by G(s)/(1+G(s) H(s)). In some embodiments, the measurement output includes the common mode error, and wherein a single signal source is used to compensate for the common mode error in the testing signal and the measurement output. In some embodiments, the measurement unit includes a resistor. In some embodiments, the method further includes communicating the voltage to the measurement subcircuit. The measurement output can include an electrical current measurement based on the feedback signal and a voltage measurement based on the voltage. In some embodiments, determining the correction factor for the testing signal includes comparing the measurement output to a lookup table. In some embodiments, applying the correction factor to the testing signal includes utilizing a calibration coefficient to adjust a signal source of the testing signal. In some embodiments, the lookup table includes associated electrical current and voltage measurements with common mode error values. In some embodiments, the feedback subcircuit shifts the common mode error. In some embodiments, a value of the voltage determined at the output signal to the DUT is indicative of the common mode error.

In some aspects, the techniques described herein relate to a semiconductor testing apparatus configured for correcting common mode error in a composite system. The semiconductor testing apparatus includes a semiconductor device tester configured to receive therein a device under test (DUT). The semiconductor testing apparatus includes a test signal source circuitry configured to provide a testing signal to the DUT, the testing signal having a common mode error. The semiconductor testing apparatus includes a measurement unit connected to the test signal source circuitry and configured to determine a voltage at an output signal to the DUT. The semiconductor testing apparatus includes a feedback subcircuit, wherein the feedback subcircuit is configured to receive the voltage and provide a feedback signal to the testing signal to compensate for the common mode error.

In some embodiments, the semiconductor testing apparatus can include measurement subcircuit configured to receive the feedback signal from the feedback subcircuit and one or more processors. The one or more processors can be configured to determine, based on a measurement output of the measurement subcircuit, a correction factor for the testing signal, the correction factor configured to compensate for the common mode error, and cause the signal source to apply the correction factor to the testing signal to compensate for the common mode error. In some embodiments, the measurement subcircuit does not have additional circuitry configured to compensate for the common mode error. In some embodiments, the test signal source circuitry has a first transfer function G(s), the feedback subcircuit has a second transfer function H(s), and a ratio of the output signal to the DUT to the testing signal is expressed as a negative feedback control system transfer function represented by G(s)/(1+G(s) H(s)). In some embodiments, the measurement output includes the common mode error, and wherein a single signal source is used to compensate for the common mode error in the testing signal and the measurement output. In some embodiments, the measurement unit includes a resistor. In some embodiments, the measurement output includes an electrical current measurement based on the feedback signal and a voltage measurement based on the voltage. In some embodiments, to determine the correction factor for the testing signal the one or more processors are configured to compare the measurement output to a lookup table. In some embodiments, the lookup table includes associated electrical current and voltage measurements with common mode error values. In some embodiments, to apply the correction factor to the testing signal the one or more processors are configured to utilize a calibration coefficient to adjust the signal source. In some embodiments, the feedback subcircuit shifts the common mode error. In some embodiments, a value of the voltage determined at the output signal to the DUT is indicative of the common mode error.

In some aspects, the techniques described herein relate to non-transitory computer storage media storing instructions that when executed by a system of one or more processors, cause the one or more processors to detect a device under test (DUT) in a semiconductor device testing system, apply a testing input signal from a test signal source circuitry to the DUT, the testing signal having a common mode error, determine, at a measurement unit connected to the test signal source circuitry, a voltage at an output signal to the DUT, communicate the voltage to a feedback subcircuit, and provide, by the feedback subcircuit, a feedback signal to the testing signal to compensate for the common mode error.

In some embodiments, the instructions further cause the one or more processors to provide, by the feedback subcircuit, the feedback signal to a measurement subcircuit, determine, based on a measurement output of the measurement subcircuit, a correction factor for the testing signal, the correction factor configured to compensate for the common mode error, and apply the correction factor to the testing signal to compensate for the common mode error. In some embodiments, the measurement output includes the common mode error, and wherein no additional circuitry is used to compensate for the common mode error in the measurement output. In some embodiments, the measurement subcircuit does not have additional circuitry configured to compensate for the common mode error. In some embodiments, a value of the voltage determined at the output signal to the DUT is indicative of the common mode error.

### BRIEF DESCRIPTION OF THE DRAWINGS

Embodiments of this disclosure will be described, by way of non-limiting example, with reference to the accompanying drawings.

FIG. 1 is a schematic diagram of a semiconductor device tester, according to various embodiments.

FIG. 2 is a schematic diagram of a semiconductor device tester including a system for correcting for common mode error, according to various embodiments.

FIGS. 3A-3C illustrate block diagrams of example transfer functions of the semiconductor device tester, according to various embodiments.

FIG. 4 is a flow chart illustrating a method of determining calibration coefficients for a calibrated input signal, according to embodiments.

FIG. 5 is a flow chart illustrating a method of correcting common mode error, according to embodiments.

FIG. 6 is a circuit diagram of components of the semiconductor device tester, according to various embodiments.

FIG. 7A is a block diagram illustrating an example source path, according to embodiments.

FIG. 7B is a block diagram illustrating an example measure path, according to embodiments.

FIG. 8 is a schematic diagram depicting a computer system adapted for determining and compensating for common mode error, according to embodiments.

### DETAILED DESCRIPTION

The following detailed description of certain embodiments presents various descriptions of specific embodiments. However, the innovations described herein can be embodied in a multitude of different ways, for example, as defined and covered by the embodiments. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the illustrated elements. Further, some embodiments can incorporate any suitable combination of features from two or more drawings.

Aspects of this disclosure relate to a system for reducing and/or compensating for error. According to various embodiments, the system can be implemented in testing electronic devices, such as semiconductor devices (referred to generally herein as devices under test (DUTs)). The system can provide a source signal (also referred to herein as a testing signal) to a DUT and can receive the resulting measured output from the DUT. The system can further process the resulting output to determine and correct for error introduced by the system. In some embodiments, the system can regulate four quadrants of positive and negative voltages and currents.

Various aspects of this disclosure relate to feedback circuitry and measuring by the system to determine and correct error at a signal to the DUT. An error signal, as used herein, can refer to a difference between a desired or theoretical output and an actual, e.g., measured, output based on a given testing signal. Many factors can contribute to the error signal in a signal chain, including error introduced by the testing system. The system error can reduce the overall accuracy of testing systems. For example, as the system error increases, it can be difficult to determine if a DUT passing or failing a test is due to the DUT or due to the error introduced by the testing system.

Various sources of system error exist in semiconductor device testing, including gain error, offset error, non-linearity error and common mode error, to name a few. Common mode error (CME) refers to error associated with signals common to multiple inputs of an apparatus, or common mode signals. A common mode level refers to a value associated with the magnitude of the common mode signals. A measure of the extent to which the common mode signals are rejected is known as a common mode rejection ratio (CMRR). Common mode error can be errors found in the common mode of a DUT. For example, common mode error can be introduced by way of a common signal (e.g., electromagnetic interference) in multiple inputs of a differential amplifier. Ideally, the differential amplifier amplifies only the difference between the signals at its two inputs and the common-mode level is subtracted to zero. As such, any common mode signals are rejected at the output of the differential amplifier. In practice, the common mode signals are not completely rejected, and can introduce error in measurements. One approach to reducing common mode error is to include compensating circuitry, e.g., on the measurement side of a DUT, to provide an additional signal source to compensate for the common mode error. However, the additional signal source can add complexity to the circuitry, increase power consumption, create additional contributions to the overall error signal, and/or take up critical area. Disclosed herein is a testing system that can correct and/or compensate for common mode error using the source signal without an additional signal source. The disclosed testing system can correct and/or compensate for common mode error with improved power consumption, performance, and efficiency in area use.

### Method of Compensating for Common Mode Error

Aspects of this disclosure relate to methods for compensating for common mode error using a correction factor applied to an input source. The disclosed methods can include a composite closed loop system. To perform error correction in a composite closed loop system, one must take care when measuring, isolating, or otherwise determining the components of the total system error contribution. The disclosed methods can utilize the source input alone to adjust the output to compensate for common mode error of the forward signal path, of the source, as well as a measured signal path. The disclosed methods can combine the source and measurement path in a composite feedback system, allowing the source input to compensate for the common mode error in the measured signal path.

The measurement path may be used to sense and/or determine the common mode error at the at the output of feedback circuitry in a composite closed loop system. The measured common mode error may be used to determine the correction factor applied to the input source. For example, the measured common mode error may be used to determine one or more calibration coefficients for the common mode error and proper correction may be applied at the input source based on the one or more calibration coefficients.

The disclosed method can include mapping measured common mode error values to one or more calibration coefficients that can be used to correct each measured common mode value. The disclosed method can further include using the mapping to dynamically adjust the input signal based on real-time common mode value measurements.

### System for Compensating for Common Mode Error

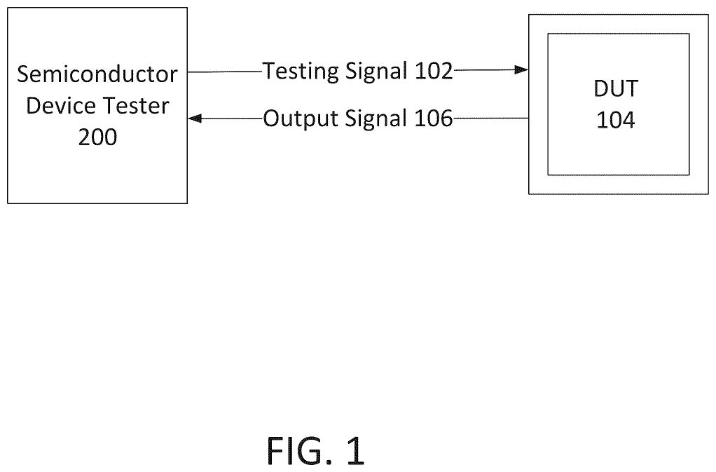

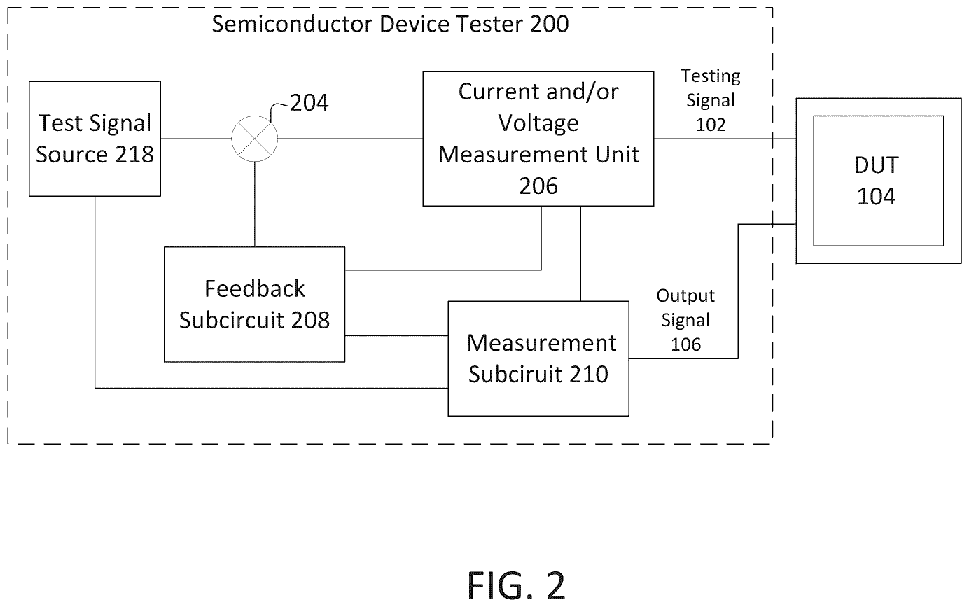

Generally, aspects of the present disclosure relate to systems and methods for compensating and/or correcting common mode error in a composite closed loop system. FIG. 1 is an illustrative example of a semiconductor device tester 200 electrically connected to a device under test (DUT) 104. The DUT 104 is configured to receive a testing signal 102 from the semiconductor device tester 200 and output an output signal 106 to the semiconductor device tester 200. FIG. 2 is an illustrative embodiment of a semiconductor device tester 200 with a composite closed loop system connected to a DUT 104. In the illustrated example, the semiconductor device tester 200 includes a test signal source 218, a summing junction 204, a current and/or voltage measurement unit 206, a measurement subcircuit 210, and a feedback subcircuit 208. As illustrated, the semiconductor device tester 200 and the DUT 104 form a closed loop circuit path. As described herein, the circuit path carrying the testing signal 102 to the DUT 104 is generally referred to herein as the source (SRC) path, and the circuit path carrying the output signal 106 is generally referred to herein as the measure (MSR) path. As described herein, a composite closed loop system refers to a system including both the SRC and the MSR path. Referring to FIG. 2, the SRC path includes the test signal source 218, the summing junction 204, the current and/or voltage measurement unit 206 and the feedback subcircuit 208, and the MSR path includes the measurement subcircuit 210.

The test signal source 218 can include a power supply that can operate in four quadrants of a voltage-current coordinate system. For instance, the test signal source 218 may be capable of supplying positive and negative voltages, sourcing current, and sinking current. In some embodiments, the test signal source 218 can be a different power supply. For example, in some embodiments the test signal source 218 may not be capable of sinking current. The test signal source 218 can include one or more digital to analog converters (DAC), waveform generators, direct digital synthesizers, and/or any signal source that can be incrementally or dynamically adjusted based on one or more calculated calibrated coefficients. The test signal source 218 can provide the testing signal 102 to the DUT 104, via the summing junction 204. The summing junction 204 can include electrical components for combining electrical signals, such as passive and active electrical circuitry (e.g., amplifiers, transistors, resistors, capacitors, and/or any suitable electrical components). According to various embodiments disclosed herein, the test signal source 218 can adjust the testing signal 102 based on a correction factor to correct and/or compensate for common mode error. The correction factor may be based on a signal received directly or indirectly from the measurement subcircuit 210. In some embodiments, the summing junction 204 can include voltage gain stages, current gain stages, integrator circuits, differential circuits, proportional circuits, and/or other suitable circuitry for implication and/or proportional-integral-derivative (PID) control and amplification. In some instances, some, or all of these PID control or amplification components may be implemented outside of the summing junction 204, such as in a separate subcircuit between the summing junction and the current and/or voltage measurement unit 206.

The testing signal 102 may be an electrical signal. An electrical signal can be an electrical current and/or voltage capable of being passed through a circuit and/or electrical/electromechanical device. Electrical signals can be steady-state, oscillating, or any combination of waveforms and amplitudes. In some embodiments, signals can correspond to positive and negative levels of current ranging from 1 nanoamps to 1000 amps. In some embodiments, signals can correspond to positive and negative levels of voltage ranging from 100 microvolts to 10000 volts. The testing signal 102 may include multiple electrical signals. For example, the testing signal 102 can include multiple offset electrical currents and/or voltages provided to the DUT 104. Each of the multiple electrical signals may include a common electrical signal component (e.g., a common voltage component), which can contribute to common mode error being present in the testing signal 102, the output signal 106, and/or other electrical signals within the semiconductor device tester 200.

The DUT 104 can be an integrated circuit (IC) device, e.g., an IC device configured as compute, memory, storage, power management and energy storage management devices, or any other electrical device composed of silicon, another semiconductor, or a combination of semiconductors. A DUT can be placed into a semiconductor device tester for various parametric testing for functionality, performance and reliability, including current, voltage, power, or any other metric. Within semiconductor device testers, some tests can include electronically connecting the testing signal 102 to one or more components of a DUT. A testing signal 102 can be electrical current and/or an electrical voltage meant to be applied to, and cause a response by, a DUT. A testing signal 102 can be configured to cause a DUT to undergo operations like computational tasks or experience conditions like specified levels of heat produced directly or indirectly by passing the testing signal 102 to and through the DUT.

The output signal 106 can be an electrical signal provided by the DUT 104 based on and/or resulting from the testing signal 102. The output signal 106 can be used to determine if the output signal 106 from the DUT 104 meets a particular test criteria the semiconductor device tester 200 is applying to the DUT 104. In addition to the intended output signal, the output signal 106 can also include an error signal, representing the difference between a theoretical output based on an ideal testing signal 102 and the actual output signal 106. The error signal can reduce the overall accuracy of the semiconductor device tester 200. For example, as the error signal increases, it can be difficult to determine if a DUT 104 passing or failing a test is due to the DUT 104 or due to the error introduced by the semiconductor device tester 200. One form of error that contributes to the overall error signal is common mode error. Accordingly, the semiconductor device tester 200 can determine the common mode error and apply a correction factor at the test signal source 218 to correct and/or compensate for the common mode error.

As part of determining the common mode error, the current and/or voltage measurement unit 206 can determine a current and/or voltage of the signal as provided to the DUT (e.g., the output signal 106). The current and/or voltage measurement unit 206 can include passive and/or active electrical circuitry for determining the current and/or voltage. In some embodiments, the current and/or voltage measurement unit 206 includes a resistor, such a variable resistor. The current and/or voltage measurement unit 206 can provide a voltage (e.g., a differential voltage) to the feedback subcircuit 208 and at least a portion of the voltage to the measurement subcircuit 210.

The feedback subcircuit 208 can be a feedback system implemented to control, regulate, and influence the output signal 106 through a desired transfer function. The feedback subcircuit 208 can include passive and active circuit elements, such as amplifiers, resistors, capacitors, and/or any suitable passive or active circuit element. In various embodiments, the feedback subcircuit 208 can amplify, reduce, shift, and/or perform other suitable operations to electrical signals. The feedback subcircuit 208 can include multiple stages, such as amplification stages, shifting stages, reduction stages, and/or other suitable stages used in feedback systems to implement the desired transfer function. The feedback subcircuit 208 can provide a feedback signal to the summing junction 204, where the feedback signal is combined into the testing signal 102 from the test signal source 218. The feedback subcircuit 208 can also provide the feedback signal to the measurement subcircuit 210.

In various embodiments, the common mode error is calibrated at the feedback subcircuit 208 from the voltage received from the current and/or voltage measurement unit 206. The total common mode level of the semiconductor device tester 200 and DUT 104 can be represented in the feedback signal provided to the summing junction 204 and the measurement subcircuit 210. Accordingly, the common mode error can be measured from the feedback signal and corrected and/or compensated for using the correction factor by the test signal source 218. In some embodiments, the common mode error associated with the voltage received from the current and/or voltage measurement unit 206 may be equivalent to and/or mapped to the common mode error associated with the feedback signal.

The measurement subcircuit 210 can measure one or more attributes of electrical signals. For example, the measurement subcircuit 210 can measure voltages, currents, electrical power, and/or make other suitable measurements of an electrical signal. In various embodiments, the measurement subcircuit 210 can operate in four quadrants of a voltage-current coordinate system (e.g., the measurement subcircuit 210 may measure both positive and negative voltages and currents). The measurement subcircuit 210 can include passive and active circuit elements, such as amplifiers, resistors, capacitors, and/or any suitable passive or active circuit element. The measurement subcircuit 210 can include any probe or other measurement device for measuring currents, voltages, and/or other measurements of an electrical signal.

In some embodiments, the measurement subcircuit 210 may take current and voltage measurements (e.g., differential voltage measurements) received from the current and/or voltage measurement unit 206 and take current measurements from the feedback signal received from the feedback subcircuit 208. The voltage measurements and current measurements may be used to calculate electrical power usage. The voltage measurements and/or the current measurements may be used to determine the correction factor the test signal source 218 applies to the testing signal 102.

As discussed above, the total common mode level of the semiconductor device tester 200 and DUT 104 can be represented in the feedback signal received by the measurement subcircuit 210. As such, the measurement subcircuit 210 does not contribute additional error to the common mode level, allowing the measurement subcircuit 210 to measure and/or determine the total common mode error and provide supporting information used to determine the correction factor applied by the test signal source 218.

In the illustrated embodiment, a measurement signal is sent from the measurement subcircuit 210 to the test signal source 218. The measurement signal can include information used for determining the correction factor, such as voltage measurements, current measurements, power measurements, and/or any other suitable measurement. In some embodiments, the measurement signal can include values for the correction factor. All, or a portion, of the correction factor can be determined by the measurement subcircuit 210 and/or the test signal source 218. In some embodiments, the measurement signal is provided to other components of the semiconductor device tester 200 (e.g., one or more processors, controllers, field programable gate arrays (FPGAs) and/or other suitable components) that can determine the correction factor and cause the test signal source 218 to apply the correction factor to the testing signal 102. The implementation of the correction factor may utilize correction coefficients. The correction coefficients, and mapping thereof to measurement signals, may consist of, or take part in, a digital or analog subsystem, mapping algorithm, lookup table, external memory, and/or other suitable applications.

According to various embodiments, because the measurement subcircuit 210 does not contribute to the total common mode error the semiconductor device tester 200 is capable of correcting and/or compensating for the common mode error in both the testing signal 102 and the measurement signal at the output of the measurement subcircuit 210 using the same correction factor applied by the test signal source 218. As such, no additional signal source is needed to correct the common mode error, allowing for improved power delivery, performance, and efficiency in area use for the semiconductor device tester 200.

### Example Transfer Function

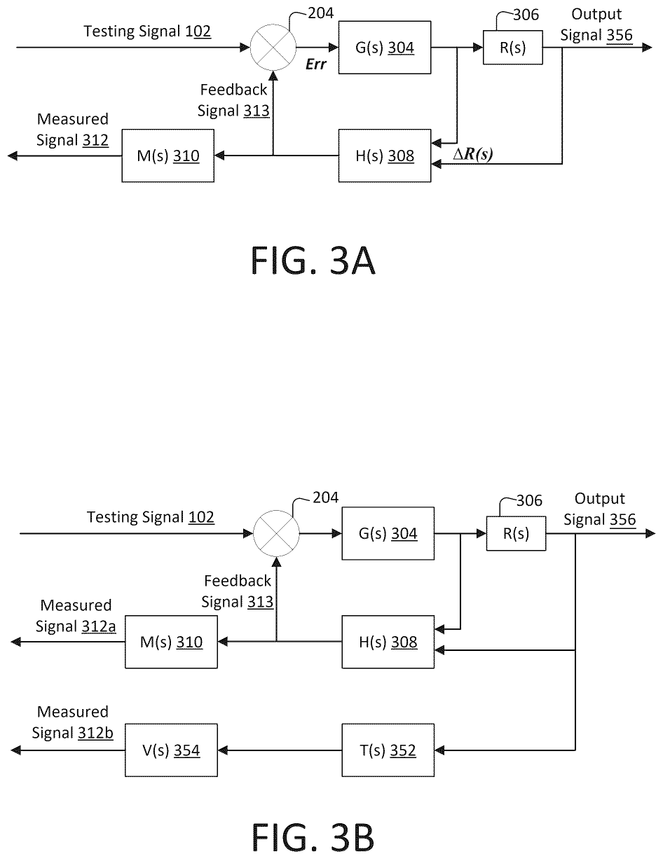

FIGS. 3A-3C illustrate block diagrams of example transfer functions of the semiconductor device tester 200, according to various embodiments. The block diagrams illustrate a testing signal 102 (“Input”), such as the testing signal 102 applied by the 218, to an output signal 356 (“Output”), such as an output to a DUT 104, and various transfer functions including those of the controlled system, G(s) as well as the feedback system, H(s). The Output may be a signal delivered to the DUT 104 as defined by manufacturer of the DUT 104. The illustrated block diagram representation is an abstraction that describes a system as an interconnection of blocks, whose input/output behavior can be described by differential equations. It will be appreciated that a transfer function, which is a function of complex variables, is a simplified representation of the differential equations describing the dynamics of the system.

Referring to FIG. 3A, the block diagram includes the testing signal 102, a summing junction 204, a first transfer function block (G(s)) 304, a second transfer function block (R(s)) 306, an output signal 356, a third transfer function block (H(s)) 308, a feedback signal 313, a fourth transfer function block (M(s)) 310, and a measured signal 312. Referring to FIG. 3B, the example transfer function can further include a fifth transfer function block (T(s)) 352 and a sixth transfer function block (V(s)) 354.

According to various embodiments, G(s) 304 represent the portion of the transfer function on the SRC path contributed by the tester to the DUT 104, R(s) 306 can represent the portion of the transfer function contributed by the current and/or voltage measurement unit 206 voltage measurement unit 206, H(s) 308 can represent the portion of the transfer function contributed by the feedback subcircuit 208, and M(s) 310 can represent all or a part of the portion of the transfer function contributed by the measurement subcircuit 210, e.g., a current measurement subcircuit. T(s) 352 and V(s) 354 can represent further portions of the transfer function contributed by the measurement subcircuit 210, e.g., a voltage measurement subcircuit, and/or other portions of the semiconductor device tester 200 used to sense and/or adjust electrical signals. The feedback signal 313 can be an electrical signal provided by the feedback subcircuit 208 to the summing junction 204 to be combined with the testing signal 102 and the measured signal 312 can be a measured signal determined by the measurement subcircuit 210. In various embodiments, the measured signal 312 can include a measured signal 312a at the output of M(s) 310 and a measured signal 312b at the output of V(s). In some embodiments, measured signal 312a represents a measured current signal and measured signal 312b represents a measured voltage signal.

Equations 1-3 provide the overall transfer function of FIGS. 3A and 3B. At the output of the summing junction 204, the error signal (“Err”) can be expressed by Equation 1, where H(s)^{+/-} represents H(s) 308, R(s) represents R(s) 306, and G(s) represents G(s) 304. Using Equation 1 to define the input of G(s) 304, the output signal 356 can be expressed by Equation 2. Equations 1 and 2 can be used to solve the overall transfer function, expressed by Equation 3.

$$Err = Input - Err * G ( s ) * {H ( s )}^{+ / -} [ 1 - R ( s ) ] \qquad ( Equation 1 )$$

$$Output = Err * G ( s ) * R ( s ) \qquad ( Equation 2 )$$

$$[ \frac{Output}{Input} ] = [ \frac{G ( s ) R ( s )}{1 + G ( s ) H ( s ) [ 1 - R ( s ) ]} ] \qquad ( Equation 3 )$$

As the error signal increases relative to an effective resolution of the Input, correction factors may be needed to optimize the transfer function. One such correction factor is the correction factor applied by the test signal source 218 of FIG. 2 used to correct for common mode error, such as the error due to the common mode level (“Err_{CML}”). Equation 4 expresses the error signal that can be expressed in terms of Err_{CML}. The Err_{CML} can be the error associated with the common mode level at H(s) 308. ΔR(s) can represent the differential voltage at the output of R(s) 306, as shown by Equation 5. The Err_{CML} can be expressed by Equation 6, where CME represents the ratio of the measured output (output signal 356) with respect to a common model level at the input of G(s) 304 or, in other words, the percentage of the total error signal due to the common mode level.

$$Err = Input - {H ( s )}^{+ / -} [ Δ R ( s ) + {Err}_{CML} ] \qquad ( Equation 4 )$$

$$Δ R ( s ) = Err * G ( s ) - Err * G ( s ) * R ( s ) = Err * G ( s ) [ 1 - R ( s ) ] \qquad ( Equation 5 )$$

$${Err}_{CML} = ( \frac{Err * G ( s ) + Err * G ( s ) * R ( s )}{2} ) CME \qquad ( Equation 6 )$$

The feedback signal 313 can expressed as the output of H(s) 308 with the sum of ΔR(s) and Err_{CML} as the input of H(s) 308. M(s) 310 may utilize the feedback signal 313 to determine a measured current (“MI”), as expressed in Equation 7. The measured signal 312 and/or the measured signal 312a may include all, or a portion, of the measured current. A measured voltage (“MV”) may be determined by T(s) 352 and/or V(s) 354 from the output of R(s), as expressed in Equation 8. In some embodiments, T(s) 352 and V(s) 354 may be combined. The measured signal 312 and/or the measured signal 312b may include all, or a portion, of the measured voltage. The overall transfer function expressed in terms of CME is expressed by Equation 9.

$$MI = M ( s ) * {H ( s )}^{+ / -} [ Δ R ( s ) + {Err}_{CML} ] \qquad ( Equation 7 )$$

$$MV = Output * T ( s ) * V ( s ) \qquad ( Equation 8 )$$

$$\frac{Output}{Input} = \frac{G ( s ) R ( s )}{1 + {H ( s )}^{+ / -} G ( s ) [ 1 - R ( s ) + 2 + \frac{CME}{2} + \frac{CME * R ( s )}{2} ]} \qquad ( Equation 9 )$$

The error signal, at the input to G(s) 304 can be removed by adjusting and/or calibrating the input signal via to null the error. When the calibrated input signal (“Input_{Cal}”) is set such that it nulls the error signal due to Err_{CML}, the calibrated input signal can be expressed by Equation 10. Equation 11 illustrates that using substituting the calibrated input signal of Equation 10 for the Input of Equation 4 can remove the Err_{CML}.

$${Input}_{Cal} = Input + {H ( s )}^{+ / -} * {Err}_{CML} \qquad ( Equation 10 )$$

$$Err = {Input}_{Cal} - {H ( s )}^{+ / -} [ Δ R ( s ) + {Err}_{CML} ] = Input + {H ( s )}^{+ / -} * Δ R ( s ) \qquad ( Equation 11 )$$

Since the error contribution of the common mode level, Err_{CML}, is part of both the MI as well as the error signal at the output of the summing junction, prior to G(s) 304, the calibrated input signal can also eliminate Err_{CML} from the MI. As noted above, the measurement subcircuit 210 does not contribute to the common mode error. Similarly, M(s) 310 does not contribute to Err_{CML}. As such, the calibrated input signal need not be adjusted to account for M(s) 310 and the same calibrated input signal can account for common mode error in both the G(s) 304 and the MI.

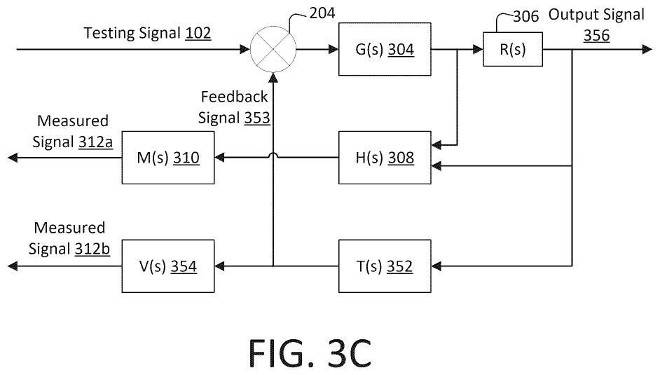

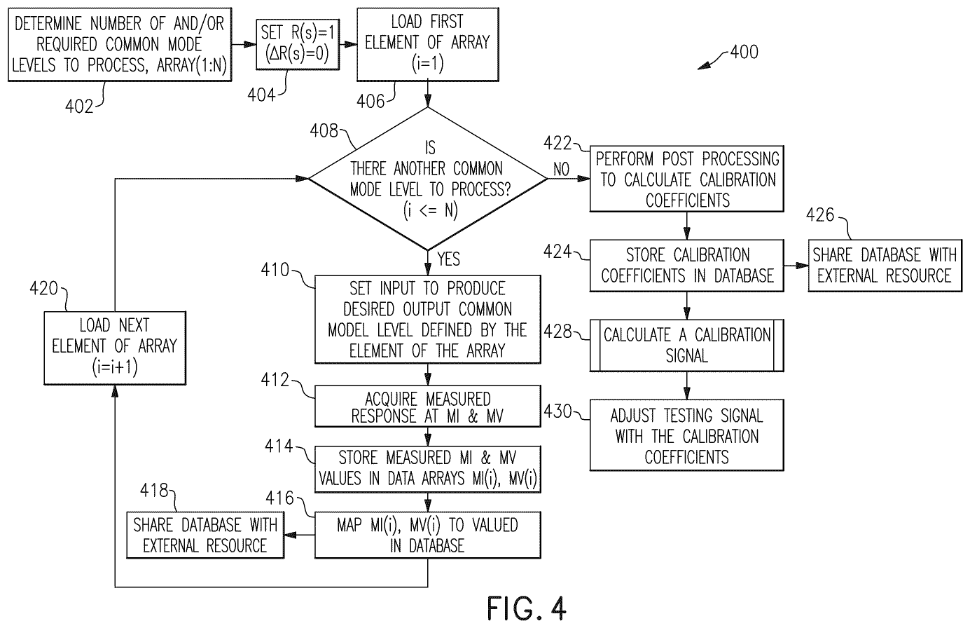

To determine values for the calibrated input signal, the common mode voltage can be measured in MV at the output of M(s) 310 and the error contribution of the common mode can be measured in MI at the output of V(s) 354. In some embodiments, to determine values for the calibrated input signal, the common mode voltage can be measured in MV at the output of V(s) 354 and the error contribution of the common mode can be measured in MI at the output of M(s) 310. The process of using measured output, such as MV and MI, to determine a correction factor for the input signal is described below with respect to FIGS. 4 and 5.

The transfer function illustrated in FIG. 3C includes analogous components to FIG. 3B. The testing signal 102, summing junction 204, G(s) 304, R(s) 306, output signal 356, H(s) 308, M(s) 310, measured signal 312a, T(s) 352, V(s) 354, and measured signal 312b may operate the same, or similarly, in the transfer function illustrated in FIG. 3C as described above with respect to FIG. 3A and/or FIG. 3B except the transfer function illustrated in FIG. 3C has a feedback signal 353 connected to the summing junction 204 from T(s) 352 rather than, or in addition to, a feedback signal connected to the summing junction 204 from H(s) 308. According to some embodiments, the transfer function illustrated in FIG. 3C may be used by a semiconductor device tester 200 to calibrate an input signal to account for common mode error using the electrical voltages (e.g., in the feedback signal 353) from T(s) 352.

### Example Processes

FIG. 4 is a flow chart illustrating a method 400 of determining calibration coefficients for a calibrated input signal, according to embodiments. In various embodiments, all, or a portion, of the method 400 may be performed by the semiconductor device tester 200 to build a mapping of measured voltages (“MV”) and measured currents (“MI”) to output common mode levels.

At block 402, the semiconductor device tester 200 determines a number of output common mode levels to process and/or required output common mode levels for processing. The number of output common mode levels to process can be represented in an array (Array(1:N), where N is the number of output common mode levels to process) with the required output common mode levels stored in each element of the array. The array may be used to determine and/or derived to fit a function to the points, 1:N. The size of the array may be based on curve fit to the function, a needed resolution, memory allocation, a lookup table, and/or other considerations.

At block 404, the semiconductor device tester 200 sets the value of R(s) to 1 such that the value of ΔR(s) is zero. For example, the semiconductor device tester 200 may bypass and/or cause the current and/or voltage measurement unit 206 to short such that both inputs to the feedback subcircuit 208 are equivalent.

At block 406, the semiconductor device tester 200 may load the first element of the array (Array(1:i=1)). At block 408, the semiconductor device tester 200 determines if the currently loaded element of the array is less than or equal to the number of output common mode levels to process (if Array(1:i) is less than or equal to N). If the currently loaded element of the array is less than or equal to the number of output common mode levels to process, method 400 proceeds to block 410. Otherwise, the method 400 proceeds to block 422.

At block 410, the semiconductor device tester 200 can set the input to produce a desired output of common mode level as defined by the currently loaded element of the array (Array(1:i). For example, the test signal source 218 may adjust the input signal such that the output has the common mode level indicated by the currently loaded element of the array.

At block 412, the semiconductor device tester 200 can acquire measured responses of MI and MV for the adjusted input signal. For example, the measurement subcircuit 210 may measure current MI values at the output of the feedback subcircuit 208 and MV values at the output of the current and/or voltage measurement unit 206 (which in this case is the same as the MV values at the output signal 356, as ΔR(s) remains zero).

At block 414, the semiconductor device tester 200 can store the measured MI values and MV values in data arrays in association with the desired output of common mode levels (Data Arrays MI (i) and MV (i) respectively). At block 416, the semiconductor device tester 200 can map the data arrays of MI values and MV values in a database to the desired output of common mode levels. The database can include lookup tables, search trees, and/or any other suitable datatypes for associating multiple values. The database can include storage media, one of more application specific integrated circuits (“ASICs”), one or more field programable gate arrays (“FPGAs”), and/or any other suitable media for temporarily or permanently storing data. At block 418, the semiconductor device tester 200 can share the database with one or more external sources, such as a database of values stored external to the semiconductor device tester 200.

At block 420, the semiconductor device tester 200 can load the next element of the array (Array(1:i=i+1)). Blocks 408 to 420 may be repeated while the array still has unprocessed output common mode levels (e.g., while block 408 remains true). As such, MI and MV values are measured, stored, and mapped for each of the required output common mode levels stored in the array. Once MI and MV values are measured, stored, and mapped for each of the required output common mode levels stored in the array, the method 400 proceeds to block 422.

At block 422 the semiconductor device tester 200 can perform post processing to calculate calibration coefficients from the measured, stored, and mapped MI and MV data. At block 424, the semiconductor device tester 200 can store the calibration coefficients in the database along with the data arrays of MI and MV data. At block 426, the semiconductor device tester 200 can share the updated database with the external sources.

At block 428, the semiconductor device tester 200 can calculate a calibration signal to common mode error from the information stored in the database. For instance, once the mapping of MI and MV values to the calibrations coefficients has been stored in the database, the semiconductor device tester 200 can sense new MI and MV values and determine from the mapping what calibration coefficients can be used to account for the new MI and MV values to correct and/or compensate for the common mode error. At block 430, the semiconductor device tester 200 can adjust the testing signal 102 with the calibration coefficients to correct and/or compensate for the common mode error. Blocks 428 and 430 are discussed in more detail in FIG. 5 below.

FIG. 5 is a flow chart illustrating a method 500 of correcting and/or compensating for common mode error, according to embodiments. In various embodiments, all, or a portion, of the method 500 may be performed by the semiconductor device tester 200.

At block 502, a DUT is provided to a semiconductor device tester, such as semiconductor device tester 200. At block 504, a testing signal, such as testing signal 102 is applied to the DUT. The testing signal can undergo additional processing before being applied to the DUT. For example, the testing signal can be amplified, attenuated, and/or otherwise processed (e.g., using G(s) 304). The DUT can output an output signal, such as output signal 106. The testing signal and/or the output signal can include common mode error that can interfere with the output signal and measured signals.

At block 506, the semiconductor device tester 200 takes a differential voltage at the input of the DUT. For example, the current and/or voltage measurement unit 206 can be used at the input of the DUT to acquire a differential voltage of a processed testing signal. At block 508 the differential voltage can be used in a feedback system. For example, the differential voltage can be used by the feedback subcircuit 208. The feedback system can be implemented to control, regulate, and influence the output signal through a desired transfer function. The feedback system can utilize the differential voltage to amplify, shift, attenuate, and/or perform other suitable operations on the differential voltage, including the common mode error in the differential voltage.

At block 510, the semiconductor device tester 200 measures current and voltage values. For example, the measurement subcircuit 210 can measure a current associated with the feedback signal at the output of the feedback subcircuit 208 and measure a voltage associated with the output of current and/or voltage measurement unit 206.

At block 512, the semiconductor device tester 200 can determine and apply a correction factor to the input signal to correct and/or compensate for the common mode error. In some embodiments, to determine the correction factor, the semiconductor device tester 200 utilize one or more databases, such as the database discussed with reference to FIG. 4, to map the measured voltages and currents to calibration coefficients that will compensate for stored common mode levels. The calibration coefficients can correspond to a correction factor applied by the semiconductor device tester 200 to the input signal. For example, the semiconductor device tester 200 can use the calibration coefficient and cause the test signal source 218 to adjust the input signal by a correction factor, such that the input signal corrects and/or compensates for common mode error that was associated with the measured voltages and currents.

### Example Circuit Components

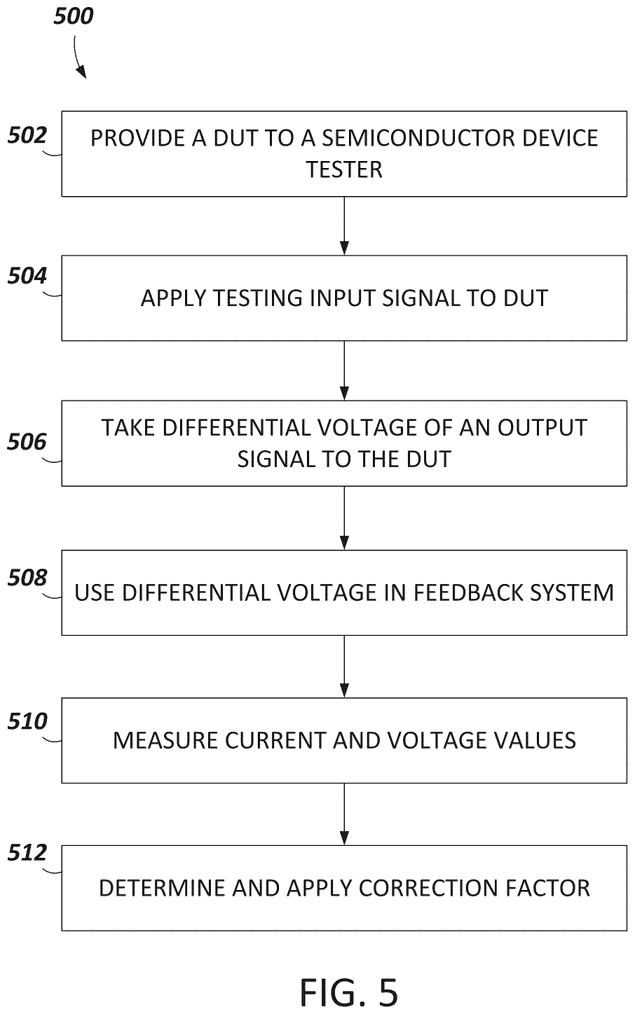

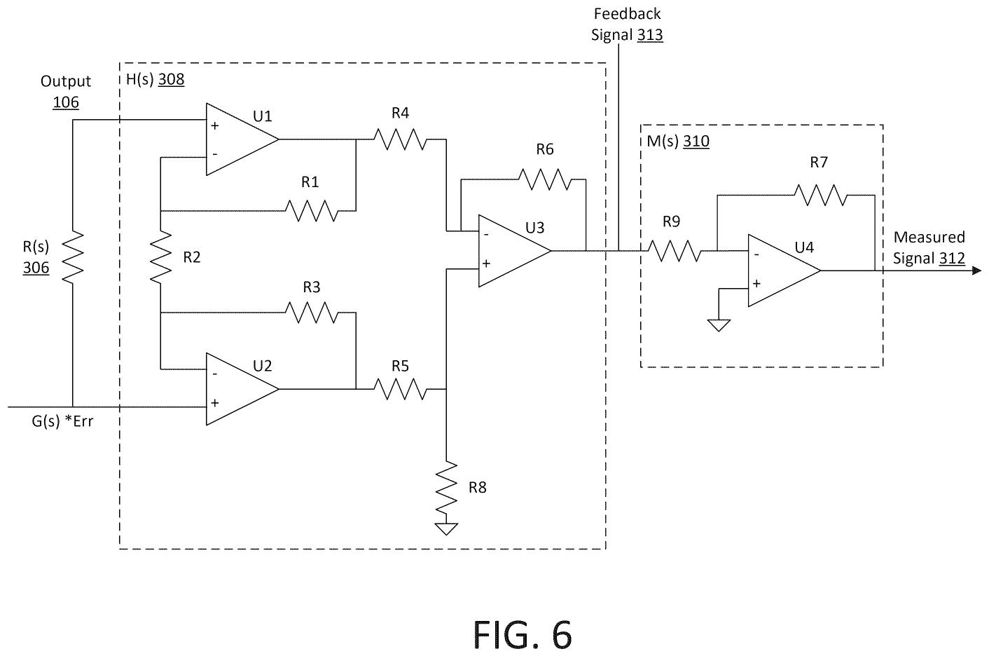

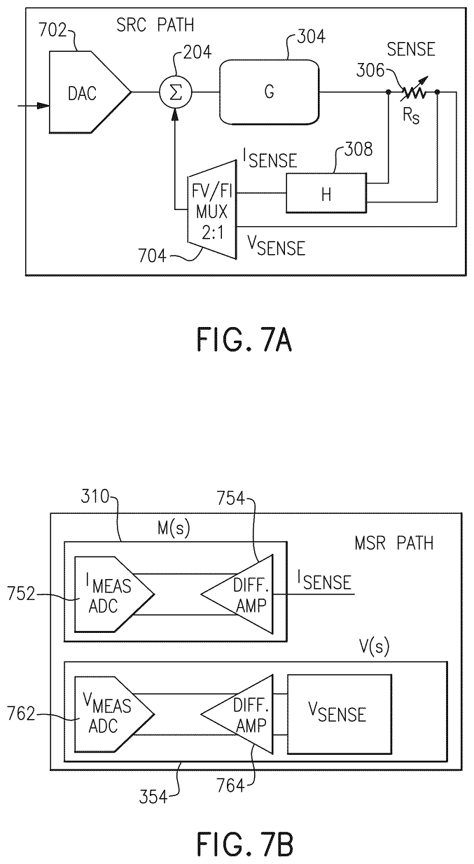

FIGS. 6, 7A and 7B illustrate example circuit components that can be used to implement portions of the semiconductor device tester 200 and/or the transfer function illustrated in FIGS. 3A and 3B. FIG. 6 is a circuit diagram illustrating the use of R(s) 306, H(s) 308, and M(s) 310 to determine a measured signal 312 and a feedback signal 313. FIG. 6 illustrates the output of G(s) 304 as used by R(s) 306 and H(s) 308. At the output of G(s) 304, the resulting signal can be expressed as G(s)*Err. The output of G(s) 304 is fed into R(s) 306, resulting in a voltage differential on each side of R(s). The differential voltage is fed into H(s) 308. The output of H(s) 308 is used as a feedback signal 313 and is fed into M(s) 310. The output of M(s) 310 is measured signal 312. In the illustrated example, measured signal 312 is a measured current (e.g., measured signal 312a illustrated in FIG. 3B).

FIG. 7A is a block diagram illustrating an example SRC path. FIG. 7B illustrates example components that can be used in the MSR path. In the illustrated example, the SRC patch includes a digital to analog converter (DAC) 702. The DAC 702 may operate as a test signal source (e.g., test signal source 218 of FIG. 2), may operate as a portion of a test signal source, and/or operate in other components. The DAC 702 may provide an analog signal to the SRC path. In the illustrated example, the SRC path includes G(s) 304, R(s) 306, and H(s) 308. R(s) 306 can output a sensed voltage (“V_{SENSE}”) and H(s) 308 can output a sensed current (“I_{SENSE}”). In some embodiments, the SRC path can include a 2 to 1 multiplexer (MUX) that can select either the V_{SENSE} or I_{SENSE} providing a single signal (e.g., a feedback signal) that is sent to the summing junction 204.

FIG. 7B is a block diagram illustrating an example MSR path. FIG. 7B illustrates example components of M(s) 310 and V(s) 354. In the illustrated example, M(s) 310 includes a differential amplifier 754 and an analog to digital converter (“ADC”) 752. M(s) 310 can take a sensed current (“I_{SENSE}”), amplify and/or shift the sensed current, and digitize the amplified and/or shifted current to be used as a measured current. For example, the measured current can be mapped to one or more calibration coefficients.

In the illustrated example, V(S) 354 includes a differential amplifier 764 and an ADC 762. V(s) 354 can take a sensed voltage (“V_{SENSE}”), amplify and/or shift the sensed voltage, and digitize the amplified and/or shifted voltage to be used as a measured voltage. For example, the measured voltage can be mapped to one or more calibration coefficients.

### Computer System

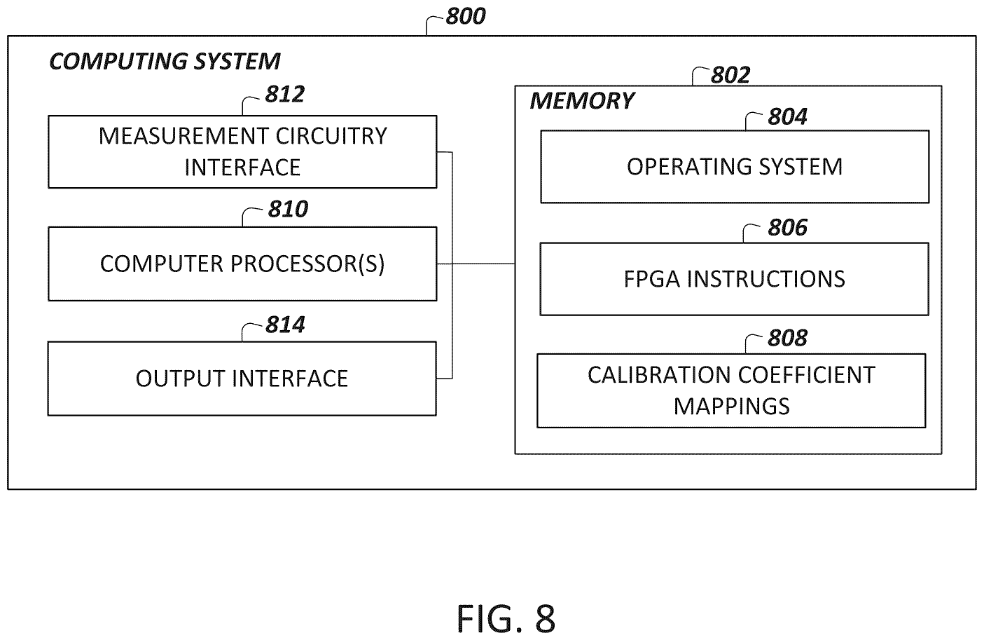

FIG. 8 illustrates an example computer system 800 that may be used in some embodiments to execute the processes and implement the features described above. In some embodiments, the computer system 800 may be used in the semiconductor device tester 200. In some embodiments, the computer system 800 may include: one or more computer processors 810, such as physical central processing units (“CPUs”) or graphics processing units (“GPUs”); computer-readable memory 802, such as high density disks (“HDDs”), solid state drives (“SDDs”), flash drives, and/or other persistent non-transitory computer-readable media; a measurement circuitry interface 812, such as an IO interface in communication between measurement circuitry, such as the measurement subcircuit 210, and the computer system 800, whereby a measured signal can be received and analyzed by the computer system 800; and an output interface 814, such as an IO interface in communication between an output signal 106 and/or an output signal 356 and the computer system 800, whereby the output signal 106 and/or the output signal 356 can be received and analyzed by the computer system 800.

The computer-readable memory 802 may include computer program instructions that the computer processor(s) 810 execute(s) in order to implement one or more embodiments. The computer-readable memory 802 can store an operating system 804 that provides computer program instructions for use by the computer processor(s) 810 in the general administration and operation of the computer system 800. The computer-readable memory 802 can also include FPGA instructions 806 for programming a field-programmable gate array (“FPGA”) for example, in some implementations an FPGA may be used as or along with the test signal source 218 to adjust a 102 based on calibration coefficients. The computer-readable memory 802 can also include calibration coefficient mappings 808 of mapped current and voltage values to calibration coefficients for the test signal source 218.

### Terminology

Depending on the embodiment, certain acts, events, or functions of any of the processes or algorithms described herein can be performed in a different sequence, can be added, merged, or left out altogether (e.g., not all described operations, sequencing, or events are necessary for the practice of the algorithm). Moreover, in certain embodiments, operations or events can be performed concurrently, e.g., through multi-threaded processing, interrupt processing, or multiple processors or processor cores or on other parallel architectures, rather than sequentially.

The various illustrative logical blocks, modules, routines, and algorithm steps described in connection with the embodiments disclosed herein can be implemented as electronic hardware, or combinations of electronic hardware and computer software. To clearly illustrate this interchangeability, various illustrative components, blocks, modules, and steps have been described above generally in terms of their functionality. Whether such functionality is implemented as hardware, or as software that runs on hardware, depends upon the particular application and design constraints imposed on the overall system. The described functionality can be implemented in varying ways for each particular application, but such implementation decisions should not be interpreted as causing a departure from the scope of the disclosure.

Moreover, the various illustrative logical blocks and modules described in connection with the embodiments disclosed herein can be implemented or performed by a machine, such as a computer processor device, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A computer processor device can be a microprocessor, but in the alternative, the processor device can be a controller, microcontroller, or state machine, combinations of the same, or the like. A processor device can include electrical circuitry configured to process computer-executable instructions. In another embodiment, a processor device includes an FPGA or other programmable device that performs logic operations without processing computer-executable instructions. A processor device can also be implemented as a combination of computer devices, e.g., a combination of a DSP and a microprocessor, a plurality of microprocessors, one or more microprocessors in conjunction with a DSP core, or any other such configuration. Although described herein primarily with respect to digital technology, a processor device may also include primarily analog components. For example, some or all of the algorithms described herein may be implemented in analog circuitry or mixed analog and digital circuitry. A computer environment can include any type of computer system, including, but not limited to, a computer system based on a microprocessor, a mainframe computer, a digital signal processor, a portable computer device, a device controller, or a computational engine within an appliance, to name a few.

The elements of a method, process, routine, or algorithm described in connection with the embodiments disclosed herein can be embodied directly in hardware, in a software module executed by a processor device, or in a combination of the two. A software module can reside in RAM memory, flash memory, ROM memory, EPROM memory, EEPROM memory, registers, hard disk, a removable disk, a CD-ROM, or any other form of a non-transitory computer-readable storage medium. An exemplary storage medium can be coupled to the processor device such that the processor device can read information from, and write information to, the storage medium. In the alternative, the storage medium can be integral to the processor device. The processor device and the storage medium can reside in an ASIC. The ASIC can reside in a user terminal. In the alternative, the processor device and the storage medium can reside as discrete components in a user terminal.

Conditional language used herein, such as, among others, “can,” “could,” “might,” “may,” “e.g.,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without other input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list.

Disjunctive language such as the phrase “at least one of X, Y, Z,” unless specifically stated otherwise, is otherwise understood with the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present.

Unless otherwise explicitly stated, articles such as “a” or “an” should generally be interpreted to include one or more described items. Accordingly, phrases such as “a device configured to” are intended to include one or more recited devices. Such one or more recited devices can also be collectively configured to carry out the stated recitations. For example, “a processor configured to carry out recitations A, B and C” can include a first processor configured to carry out recitation A working in conjunction with a second processor configured to carry out recitations B and C.

While the above detailed description has shown, described, and pointed out novel features as applied to various embodiments, it can be understood that various omissions, substitutions, and changes in the form and details of the devices or algorithms illustrated can be made without departing from the spirit of the disclosure. As can be recognized, certain embodiments described herein can be embodied within a form that does not provide all of the features and benefits set forth herein, as some features can be used or practiced separately from others. The scope of certain embodiments disclosed herein is indicated by the appended claims rather than by the foregoing description. All changes which come within the meaning and range of equivalency of the claims are to be embraced within their scope.

1. A method of correcting common mode error in a composite closed-loop system, the method comprising:
providing a device under test (DUT) in a semiconductor device testing system;
applying a testing input signal from a test signal source circuitry to the DUT, the testing signal having a common mode error;
determining, at a measurement unit connected to the test signal source circuitry, a voltage at an output signal to the DUT;
communicating the voltage to a feedback subcircuit; and
providing, by the feedback subcircuit, a feedback signal to the testing signal to compensate for the common mode error.

2. The method of claim 1, further comprising:
providing, by the feedback subcircuit, the feedback signal to a measurement subcircuit,
determining, based on a measurement output of the measurement subcircuit, a correction factor for the testing signal, the correction factor configured to compensate for the common mode error; and
applying the correction factor to the testing signal to compensate for the common mode error.

3. The method of claim 2, wherein the measurement subcircuit does not have additional circuitry configured to compensate for the common mode error.

4. The method of claim 1, wherein the test signal source circuitry has a first transfer function G(s), the feedback subcircuit has a second transfer function H(s), and a ratio of the output signal to the DUT to the testing input signal is expressed as a negative feedback control system transfer function represented by G(s)/(1+G(s) H(s)).

5. The method of claim 2, wherein the measurement output includes the common mode error, and wherein a single signal source is used to compensate for the common mode error in the testing signal and the measurement output.

6. The method of claim 1, wherein the measurement unit comprises a resistor.

7. The method of claim 2, further comprising:
communicating the voltage to the measurement subcircuit;
wherein the measurement output comprises an electrical current measurement based on the feedback signal and a voltage measurement based on the voltage.

8. The method of claim 2, wherein determining the correction factor for the testing signal comprises comparing the measurement output to a lookup table.

9. The method of claim 2, wherein applying the correction factor to the testing signal comprises utilizing a calibration coefficient to adjust a signal source of the testing signal.

10. The method of claim 8, wherein the lookup table comprises associated electrical current and voltage measurements with common mode error values.

11. The method of claim 1, wherein the feedback subcircuit shifts the common mode error.

12. The method of claim 1, wherein a value of the voltage determined at the output signal to the DUT is indicative of the common mode error.

13.-24. (canceled)

25. Non-transitory computer storage media storing instructions that when executed by a system of one or more processors, cause the one or more processors to:
detect a device under test (DUT) in a semiconductor device testing system;
apply a testing input signal from a test signal source circuitry to the DUT, the testing signal having a common mode error;
determine, at a measurement unit connected to the test signal source circuitry, a voltage at an output signal to the DUT;
communicate the voltage to a feedback subcircuit; and
provide, by the feedback subcircuit, a feedback signal to the testing signal to compensate for the common mode error.

26. The non-transitory computer storage media of claim 25, wherein the instructions further cause the one or more processors to:
provide, by the feedback subcircuit, the feedback signal to a measurement subcircuit,
determine, based on a measurement output of the measurement subcircuit, a correction factor for the testing signal, the correction factor configured to compensate for the common mode error; and
apply the correction factor to the testing signal to compensate for the common mode error.

27. The non-transitory computer storage media of claim 25, wherein the measurement output includes the common mode error, and wherein no additional circuitry is used to compensate for the common mode error in the measurement output.

28. The non-transitory computer storage media of claim 26, wherein the measurement subcircuit does not have additional circuitry configured to compensate for the common mode error.

29. The non-transitory computer storage media of claim 25, wherein a value of the voltage determined at the output signal to the DUT is indicative of the common mode error.

30. The non-transitory computer storage media of claim 25, wherein the test signal source circuitry has a first transfer function G(s), the feedback subcircuit has a second transfer function H(s), and a ratio of the output signal to the DUT to the testing input signal is expressed as a negative feedback control system transfer function represented by G(s)/(1+G(s) H(s)).

31. The non-transitory computer storage media of claim 26, wherein to determine the correction factor for the testing signal, the instructions cause the one or more processors to compare the measurement output to a lookup table.

32. The non-transitory computer storage media of claim 26, wherein to apply the correction factor to the testing signal, the instructions cause the one or more processors to utilize a calibration coefficient to adjust a signal source of the testing signal.
